(19) United States
(12) Patent Application Publication
(10) Pub. No.: US 2025/0183094 A1
(43) Pub. Date: Jun. 5, 2025

(54) METHODS FOR IMPROVING DEPTH LOADING IN TRANSISTORS

(71) Applicant: Taiwan Semiconductor Manufacturing Company, LTD., Hsinchu (TW)

(72) Inventors: Tzu-Ging Lin, Kaohsiung (TW); Jun-Ye Liu, Hsinchu (TW); Chun-Liang Lai, Hsinchu (TW); Ai Hsuan Lee, Hsinchu (TW); Yun-Chen Wu, Hsinchu (TW)

(21) Appl. No.: 18/526,529

(22) Filed: Dec. 1, 2023

(51) Int. Cl. H01L 21/762; H01L 27/088

(52) U.S. Cl. CPC H01L 21/76229; H10D 84/83

(57) ABSTRACT

Method for reducing the depth loading of dielectric structures on a substrate are disclosed. The substrate includes a set of isolated long dummy gate regions and a set of dense long dummy gate regions. Each dummy gate region is surrounded on each lateral side by a dielectric spacer and a continuous etch stop layer. A hard mask layer is formed over the substrate to exert a force that reduces stresses within the substrate. Each dummy gate is then etched to form an isolation volume and a trench in the substrate, and then filled with dielectric material to form a dielectric structure. The depth loading, or the difference in trench depths between the set of isolated long dielectric structures and the set of dense short dielectric structures, is thus reduced.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view describing the differences between isolated trenches and dense trenches.

FIG. 1B is a plan view generally illustrating an ideal situation in which zero strain or stress is present.

FIG. 1C is a set of plan views illustrating the ideal situation of zero strain or stress in an isolated long trench, an isolated short trench, dense long trenches, and dense short trenches.

FIG. 2A is a plan view generally illustrating the use of compressive stresses or forces to improve depth loading of a CPODE structure.

FIG. 2B is a set of plan views illustrating the use of compressive stresses or forces in an isolated long trench, an isolated short trench, dense long trenches, and dense short trenches.

FIG. 3A is a plan view generally illustrating the use of tensile stresses or forces to improve depth loading of a CPODE structure.

FIG. 3B is a set of plan views illustrating the use of tensile stresses or forces in an isolated long trench, an isolated short trench, dense long trenches, and dense short trenches.

FIG. 4 is a flow chart illustrating a first method for reducing depth loading of dielectric structures of a substrate for a semiconducting device, in accordance with some embodiments.

FIGS. 5A-5D are different views of a partially-completed substrate prior to starting the method of FIG. 4. FIG. 5A is a plan view. FIG. 5B is an X-axis view of the substrate along line X-X of FIG. 5A. FIG. 5C is a Y-axis view of the substrate along line Y1-Y1 of FIG. 5A. FIG. 5D is a Y-axis view of the substrate along line Y2-Y2 of FIG. 5A.

FIGS. 6A-6C are different views of the substrate after a hard mask layer is applied. FIG. 6A is an X-axis view of the substrate along line X-X of FIG. 5A. FIG. 6B is a Y-axis view of the substrate along line Y1-Y1 of FIG. 5A. FIG. 6C is a Y-axis view of the substrate along line Y2-Y2 of FIG. 5A.

FIGS. 7A-7C are different views of the substrate after patterning layers are applied. FIG. 7A is an X-axis view of the substrate along line X-X of FIG. 5A. FIG. 7B is a Y-axis view of the substrate along line Y1-Y1 of FIG. 5A. FIG. 7C is a Y-axis view of the substrate along line Y2-Y2 of FIG. 5A.

FIGS. 8A-8C are different views of the substrate after patterning the hard mask layer. FIG. 8A is an X-axis view of the substrate along line X-X of FIG. 5A. FIG. 8B is a Y-axis view of the substrate along line Y1-Y1 of FIG. 5A. FIG. 8C is a Y-axis view of the substrate along line Y2-Y2 of FIG. 5A.

FIGS. 9A-9C are different views of the substrate after exposed dummy gates are removed. FIG. 9A is an X-axis view of the substrate along line X-X of FIG. 5A. FIG. 9B is a Y-axis view of the substrate along line Y1-Y1 of FIG. 5A. FIG. 9C is a Y-axis view of the substrate along line Y2-Y2 of FIG. 5A.

FIGS. 10A-10C are different views of the substrate after exposed dummy oxide layers are removed to obtain an isolation volume. FIG. 10A is an X-axis view of the substrate along line X-X of FIG. 5A. FIG. 10B is a Y-axis view of the substrate along line Y1-Y1 of FIG. 5A. FIG. 10C is a Y-axis view of the substrate along line Y2-Y2 of FIG. 5A.

FIGS. 11A-11C are different views of the substrate after exposed portions of the semiconducting fin(s) are removed to form a trench in the substrate. FIG. 11A is an X-axis view of the substrate along line X-X of FIG. 5A. FIG. 11B is a Y-axis view of the substrate along line Y1-Y1 of FIG. 5A. FIG. 11C is a Y-axis view of the substrate along line Y2-Y2 of FIG. 5A.

FIGS. 12A-12C are different views of the substrate after the trench and isolation volume are refilled with dielectric material(s) to form an electrically isolating structure. FIG. 12A is an X-axis view of the substrate along line X-X of FIG. 5A. FIG. 12B is a Y-axis view of the substrate along line Y1-Y1 of FIG. 5A. FIG. 12C is a Y-axis view of the substrate along line Y2-Y2 of FIG. 5A.

FIGS. 13A-13C are different views of the substrate after a planarizing step. FIG. 13A is an X-axis view of the substrate along line X-X of FIG. 5A. FIG. 13B is a Y-axis view of the substrate along line Y1-Y1 of FIG. 5A. FIG. 13C is a Y-axis view of the substrate along line Y2-Y2 of FIG. 5A.

FIGS. 14A-14C are different views of the substrate after exposed dummy gates and sacrificial layers in the semiconducting fin(s) are removed. FIG. 14A is an X-axis view of the substrate along line X-X of FIG. 5A. FIG. 14B is a Y-axis view of the substrate along line Y1-Y1 of FIG. 5A. FIG. 14C is a Y-axis view of the substrate along line Y2-Y2 of FIG. 5A.

FIGS. 15A-15D are different views of the substrate after gate oxide layers have been deposited upon the semiconducting channels and electrically conductive gate material has been applied to obtain gate-all-around (GAA) transistors. The transistors are separated by a set of isolated long CPODE structures and a set of dense short CPODE structures. The dummy gate material is used to define the set of short CPODE structures. FIG. 15A is a plan view. FIG. 15B is an X-axis view of the substrate along line X-X of FIG. 15A. FIG. 15C is a Y-axis view of the substrate along line Y1-Y1 of FIG. 15A. FIG. 15D is a Y-axis view of the substrate along line Y2-Y2 of FIG. 15A.

FIG. 16 is a magnified X-axis view showing certain relationships between the dummy gate region, dielectric spacers, and etch stop layers.

FIG. 17 is a line drawing of a CPODE structure indicating where measurements were made during experiments of the present disclosure.

FIG. 18 is an illustration of example CPODE structures formed according to the methods of the present disclosure. The bending effects for isolated long trenches and dense short trenches are shown.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

The term “stress” refers to the force applied to a material per unit area. The term “strain” refers to the change in the shape of the material that results from the applied force. It is noted that in the present disclosure, these terms may be used interchangeably in some contexts.

The present disclosure relates to methods and systems for reducing depth loading of dielectric structures that electrically isolate adjacent transistors, especially with respect to Gate-All-Around (GAA) transistors. A continuous poly on diffusion edge (CPODE) structure or pattern is used as an electrically insulating or dielectric feature on the wafer substrate between transistors. The CPODE structure is formed by etching away one or more semiconducting fins and forming a trench in the substrate where each fin was originally located, and then filling the trench with a dielectric material. This provides electrical isolation between neighboring active device regions, such as transistors.

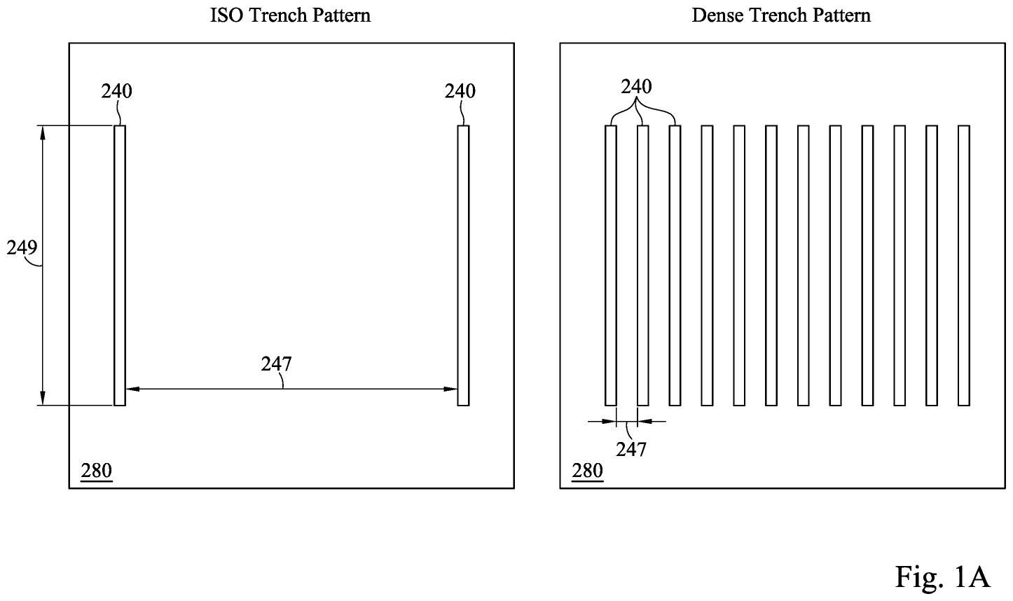

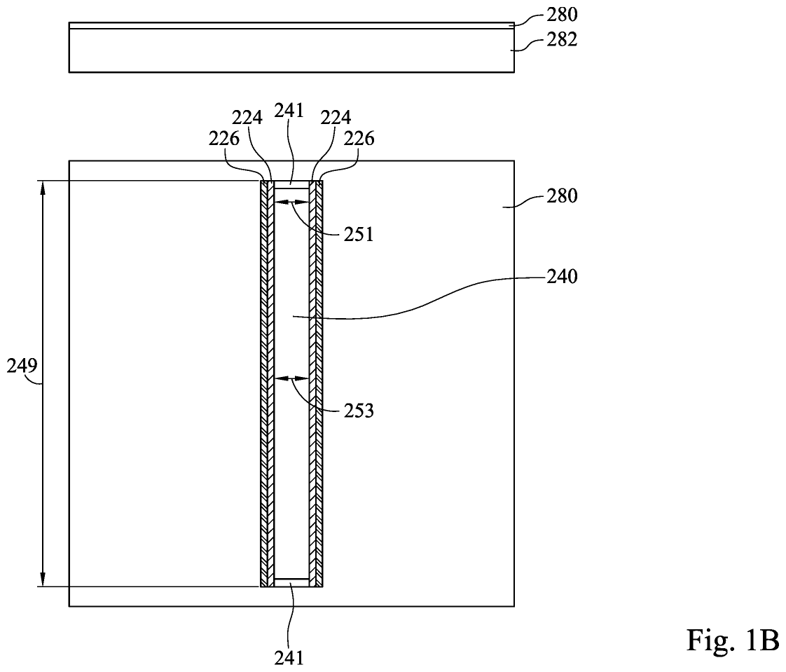

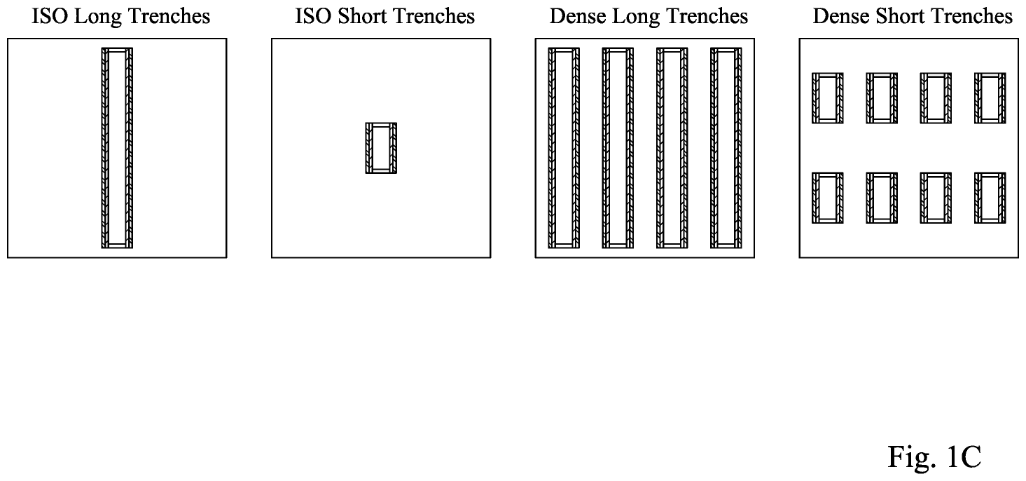

The term “depth loading” as used herein refers to the difference between etch depths of CPODE structures between a set of isolated long trenches/structures and a set of dense short trenches/structures. FIG. 1A is a plan view that illustrates the meaning of these terms. The left-hand side illustrates the layout of an isolated (ISO) trench pattern upon a hard mask layer 280. Adjacent trenches are spaced widely apart. In particular embodiments, the spacing or distance 247 between adjacent trenches 240 is 10 micrometers (10,000 nanometers) or more in an isolated trench pattern. The right-hand side illustrates the layout of a dense trench pattern. Adjacent trenches are spaced closely apart. In particular embodiments, the spacing 247 between adjacent trenches is one micrometer (1,000 nanometers) or less in a dense trench pattern, and in more specific embodiments is about 100 nanometers. The length of the trenches is indicated with reference numeral 249. Short trenches have a length of less than 500 nm, and in some particular embodiments 150 nm or less. Long trenches have a length of 500 nm or greater, and in some particular embodiments one micrometer or longer. FIG. 1A also illustrates the difference in surface area that is etched when forming an isolated trench pattern compared to a dense trench pattern.

In this regard, it is known that the etch rate varies with the amount of the substrate area being etched, and this is called the loading effect. Specifically, etching a larger surface area results in a decreased etch rate relative to etching a smaller surface area. In addition, the etch rate is lower in smaller features compared to larger features. Thus, if there is a large range of feature sizes across the substrate area being etched, the larger features will etch faster than the smaller ones. This also affects the resulting etch uniformity. The loading effect is most severe for isolated long trenches. Because the two sets of trenches/structures of FIG. 1A vary in their surface area and feature size, etch non-uniformity occurs which is measured by the depth loading. Higher uniformity, or in other words a depth loading closer to zero, is desired.

The methods of the present disclosure affect the depth loading by changing the stresses that are applied to the substrate during the etching step in forming the CPODE structure. In this regard, the substrate can be warped due to mechanical stresses. Mechanical stresses may arise due to, for example, the differences in the coefficient of expansion between different layers or due to the heterogeneous distribution of material on the substrate, which can result in uneven or unequal expansion or contraction. In the present disclosure, the composition of the hard mask layer is changed to apply a stress that counteracts the stresses of the other layers of the substrate. This provides control over the critical dimension (CD) of the CPODE structure and its depth, and thus control over the depth loading.

FIG. 1B illustrates an ideal condition, in which the total strain on the substrate is zero. As seen in the cross-sectional view of FIG. 1B, a hard mask layer 280 is present upon a substrate 202. The substrate is flat, or the surface area of the top surface is equal to the surface area of the bottom surface. In the plan view of FIG. 1B, the hard mask layer 280 is visible, along with a trench 240 upon the substrate. The trench may be formed by removal of a dummy gate material. The trench has a length 249 in the lateral direction. Two dielectric spacers 224 extend in the lateral direction, and directly contact opposite sides of the trench. Two continuous etch stop layers (CESLs) 226 also extend in the lateral direction, and directly contact the sides of the dielectric spacers 224 opposite the trench 240. Two longitudinal sidewalls 241 are present at opposite ends of the trench 240, and are typically formed from the dummy gate material. As illustrated here, the width 251 of the trench is the same at the two ends near the longitudinal sidewalls as the width 253 at the center of the trench. FIG. 1C illustrates the same conditions occurring in an isolated long trench, isolated short trenches, dense long trenches, and dense short trenches, where the widths of the trenches do not change between the ends and the center.

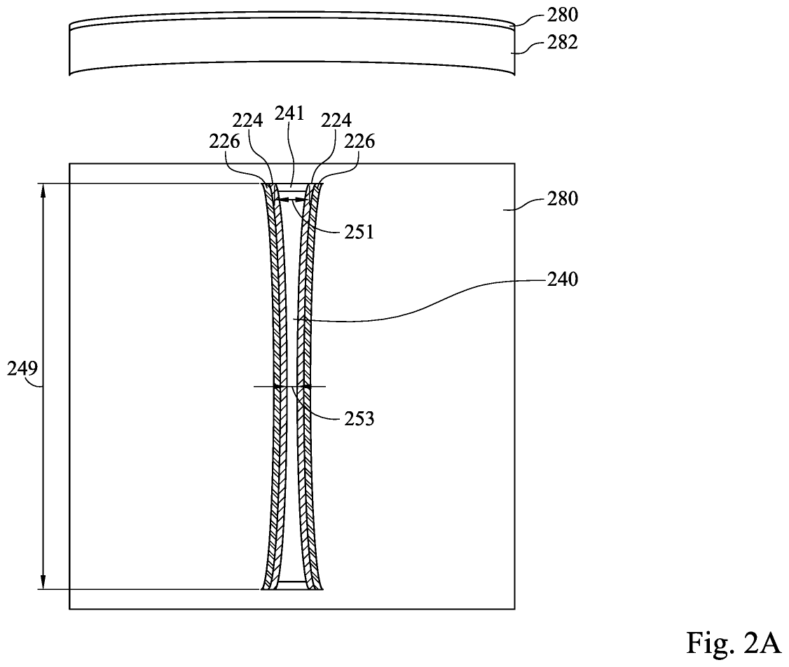

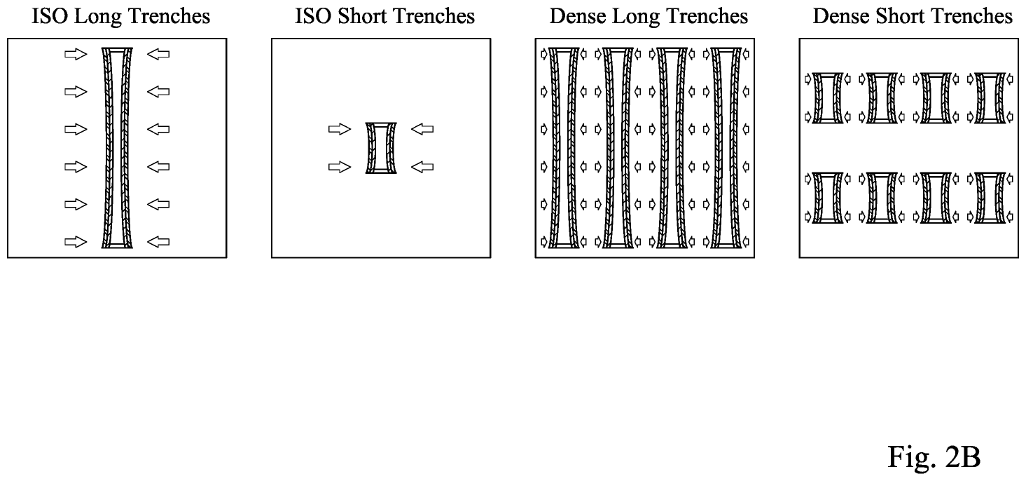

FIGS. 2A-2B generally illustrate one concept for controlling the depth loading. As seen in the top portion of FIG. 2A, a hard mask layer 280 is present upon a substrate 202. The substrate is illustrated as having a concave shape, where the surface area of the top surface is greater than the surface area of the bottom surface. The hard mask layer can be made or formed so as to exert a compressive stress to shrink the surface area of the top surface.

As illustrated in the plan view of FIG. 2A, the width 251 of the trench at the two ends near the longitudinal sidewalls is greater than the width 253 at the center of the trench. This occurs because the Young's modulus of the dielectric spacers 224 can be less than the Young's modulus of the longitudinal sidewalls 241, and can also be less than the Young's modulus of the CESLs 226, and can also be less than the Young's modulus of the hard mask layer 280. Thus, the shape of the trench/dummy gate region is controlled by the materials having the higher Young's modulus. In this compressive stress scenario, the various layers thus flex into the trench. FIG. 2B illustrates the same conditions occurring in an isolated long trench, isolated short trenches, dense long trenches, and dense short trenches.

In particular embodiments, the dielectric spacers have a Young's modulus of 75 GPa or less. In particular embodiments, the CESLs have a Young's modulus of about 250 GPa or higher. In particular embodiments, the material used to form the longitudinal sidewalls (such as the dummy gate material) has a Young's modulus of about 140 GPa to about 180 GPa.

In particular embodiments, the hard mask layer is formed from silicon nitride (SiₓN_{y}, 0<x, y≤1). The dielectric spacer is, in particular embodiments, made from a silicon oxide (SiO_{y}, 0<y≤1) or silicon carboxynitride (SiCₓO_{y}N_{z}, 0<y≤1, 0≤x, z≤1). With respect to the dielectric spacer, a higher O concentration results in a lower Young's modulus that makes this layer easier to deform. In more specific embodiments, the dielectric spacer material has a (carbon+nitrogen) content of less than 5 mole %, to reduce parasitic capacitance.

In particular embodiments, the CESL is also formed from silicon nitride. Its composition can also be varied to change the stress applied to the trench. In particular embodiments, the dummy gate material is used to form the longitudinal sidewalls of the trench, and is polysilicon. Similarly, the materials for the other components on the substrate can also be selected to tune the degree of deformation and balance that property with other required characteristics for the semiconductor device. The following table includes information about various materials which may be relevant to the present disclosure.

TABLE A

| | Dielectric Constant | Young's Modulus | |
|---|---|---|---|
| Material | (k) | (E, GPa) | Use |
| Si | 11.7 | 140-180 | Dummy Gate |
| SiC | 9.7 | 410 | |
| SiN | 7-8 | 280-290 | CESL, hard mask |
| SiO2 | 3.9 | 75 | ILD, dielectric spacer |
| SiCON | ≤5 | ≤75 | dielectric spacer |
| W | | 405 | Metal gate |
| TiN | | 260-600 | Metal gate |
| TiAl | | 236-270 | Metal gate |

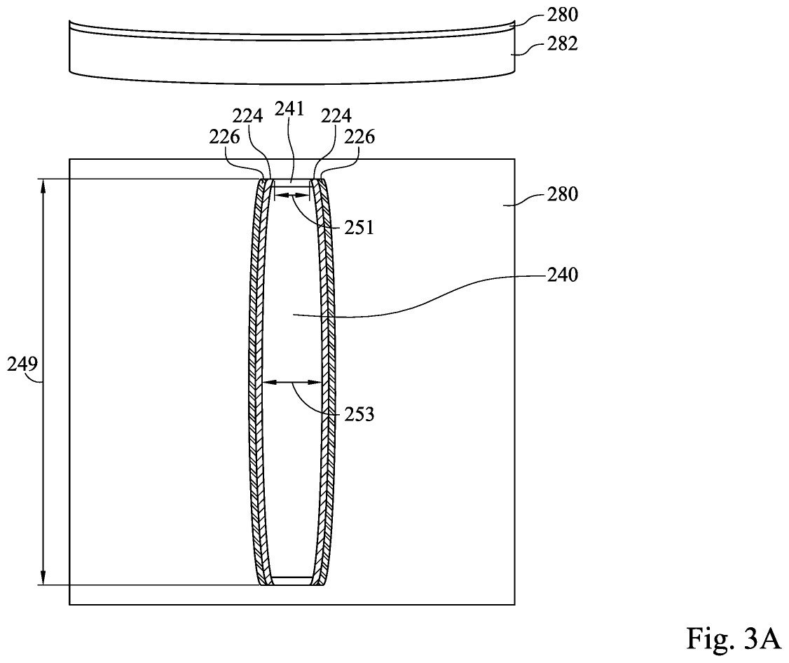

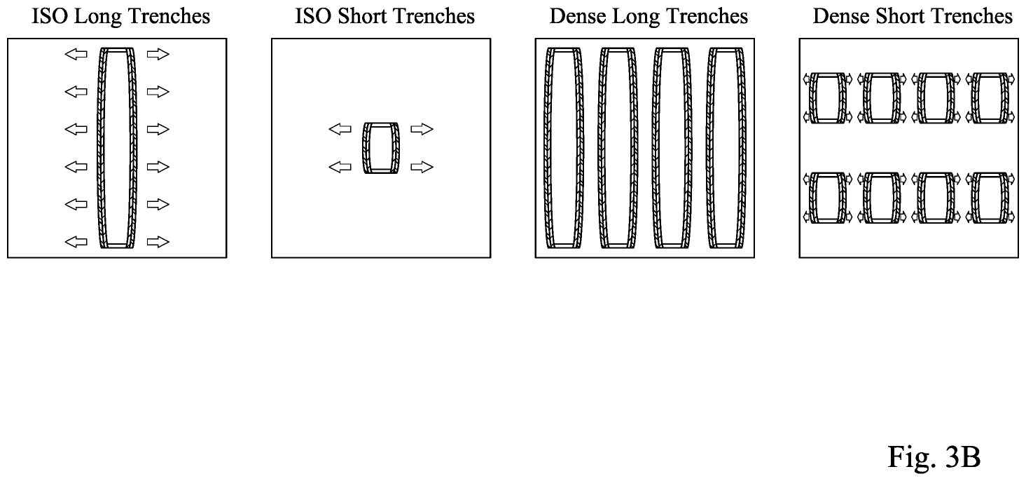

FIGS. 3A-3B generally illustrate another concept for controlling the depth loading. In the top portion of FIG. 3A, the substrate is illustrated as having a convex shape, where the surface area of the top surface is less than the surface area of the bottom surface. The hard mask layer is made or formed so as to exert a tensile stress to enlarge the surface area of the top surface.

As illustrated in the plan view of FIG. 3A, the width 251 of the trench at the two ends near the longitudinal sidewalls is greater than the width 253 at the center of the trench. Again, this occurs because the shape of the trench/dummy gate region is controlled by the materials having the higher Young's modulus, i.e. the hard mask layer 280. In this compressive stress scenario, the various layers are thus “pulled” away from into the trench. FIG. 3B illustrates the same conditions occurring in an isolated long trench, isolated short trenches, dense long trenches, and dense short trenches.

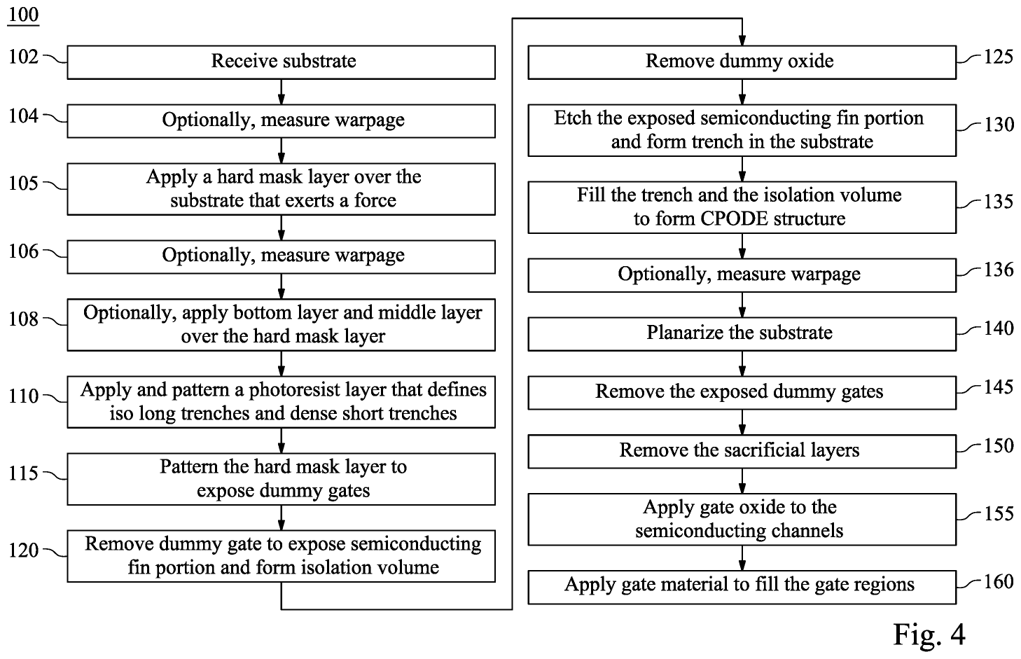

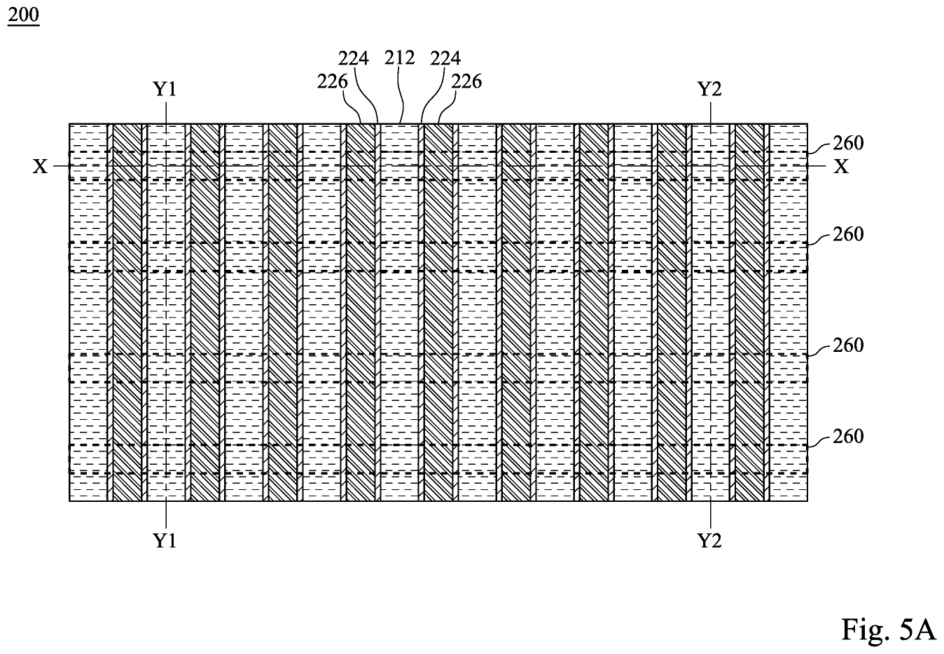

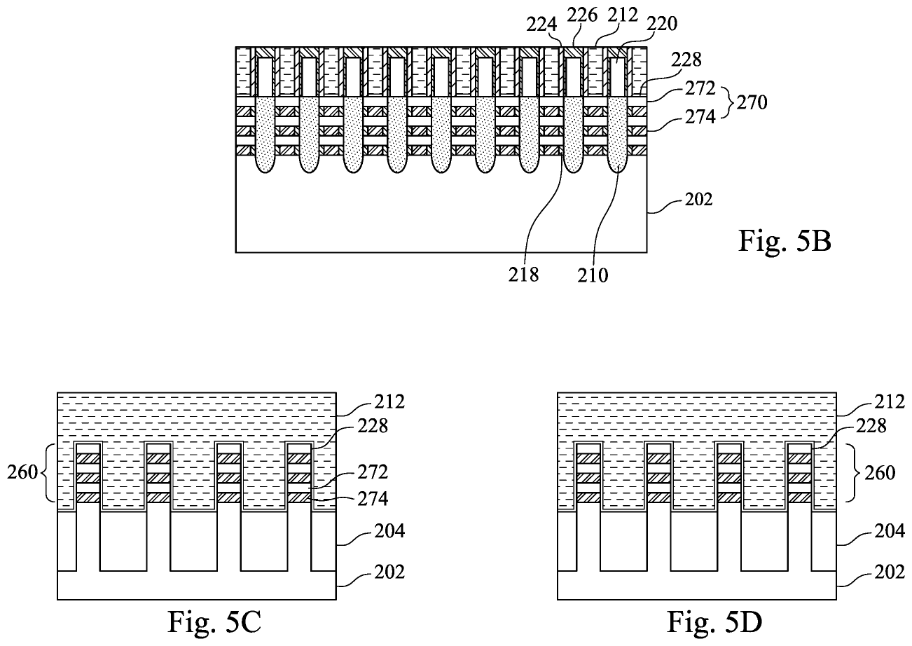

FIG. 4 is a flow chart illustrating a first method 100 for reducing the depth loading of dielectric structures on a substrate, in accordance with some embodiments. The method is useful for electrically isolating transistors which are placed upon the substrate at different densities (i.e. transistors per unit area). FIGS. 5A-15C illustrate various steps of the method, and these figures are discussed together. These figures provide different views for better understanding.

It is noted that certain conventional steps are not completely described each time in the discussion below, and may be merely referred to with respect to their result. For example, a pattern/structure may be formed in a given layer by applying a photoresist layer, patterning the photoresist layer, developing the photoresist layer, and then etching, but the discussion below may refer only to patterning the given layer. For completeness, some of these various steps are described now.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The methods and systems of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Continuing, then, FIGS. 5A-5D show a beginning state of a partially completed integrated circuit 200 on the wafer substrate 202 as received in step 102 of FIG. 4, before the method steps are performed. Referring first to the plan view of FIG. 5A, a plurality or set of long dummy gate regions 212 is shown extending in a lateral direction. Located between each pair of dummy gates 212 are a pair of low-k dielectric spacers 224 and a continuous etch stop layer (CESL) 226. The dotted lines indicate the location of semiconducting fins 260 below the dummy gates 212, the dielectric spacers 224, and the CESLs 226. As illustrated in this example, there are four semiconducting fins which extend in a longitudinal direction.

Two Y-axis views are provided in FIG. 5C and FIG. 5D through lines Y1-Y1 and lines Y2-Y2. These will illustrate the differences between isolated long trenches and dense short trenches, as will become evident.

Referring now to FIG. 5B, an X-axis cross-sectional view is provided. The integrated circuit is built upon a substrate 202. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

As most easily seen in the Y-axis views of FIG. 5C and FIG. 5D, Continuing, a shallow trench isolation (STI) region or layer 204 is present upon the substrate 202 around the semiconducting fins. The dielectric material in the STI layer is commonly silicon dioxide, although other dielectric materials can also be used such as undoped polysilicon, silicon oxide (e.g. SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. The STI layer is usually deposited prior to building the various layers of the semiconducting fins 260. If desired, the dielectric material can be deposited to a level above that of the substrate, then recessed back down to the desired height.

Each fin contains a stack 270 formed by alternating layers of a semiconducting nanosheet 272 and a sacrificial layer 274. These layers can be made using CVD, atomic layer deposition (ALD), molecular beam epitaxy (MBE), liquid phase epitaxy (LPE), liquid phase epitaxy (VPE), or any other appropriate process. Each semiconducting nanosheet layer may be, for example, silicon or other materials suitable for the substrate. The sacrificial layers 274 can be made of any suitable material which can be selectively etched in comparison to the other materials that will be used in the transistor, such as for example SiGe.

Also present are source/drain regions 210 located within the fins. In particular embodiments, these regions are formed from epitaxial silicon using CVD, MOCVD, MBE, LPE, VPE, UHVCVD, or the like. They may also be doped with appropriate dopants such as boron, gallium, or indium; or phosphorus or arsenic. Inner dielectric spacers 218 separate the source/drain regions from the sacrificial layers 274 (which will eventually be removed and filled with electrically conductive gate material).

Continuing, interlayer dielectric (ILD) regions 220 and dummy gate regions 212 and CESL 226 are placed in alternating fashion over the substrate. As can be seen in FIG. 5B, the ILD regions 220 are aligned with and placed over the source/drain regions 210.

The ILD regions electrically separate the source/drain regions from the final gate terminals or electrodes. The ILD regions may be formed from any dielectric material, and do not need to be a high-k dielectric material. Suitable dielectrics could include silicon nitride, a silicon oxide (e.g. SiO₂), phosphosilicate glass (PSG), fluorosilicate glass (FSG), undoped silicate glass (USG), high-stress undoped silicate glass (HSUSG), borosilicate glass (BSG), or any combination thereof. The ILD can be deposited using any appropriate method, for example CVD. The ILD regions 220 are surrounded on three sides (top and sides) by the CESL 226. The CESL is commonly made from silicon nitride.

Located between the ILD regions are dummy gate regions 212. The dummy gate region is typically formed from polysilicon, and is used to define the shape of the final gate terminal or electrode. The vertical surfaces of the dummy gate regions 212 are covered with a low-k dielectric spacer 224 having a dielectric constant equal to or less than that of silicon nitride (˜7). Suitable materials may include various nitrides or oxides. The CPODE structures are typically formed where a dummy gate region is located.

A dummy oxide layer 228 is located between the fin portions and the dummy gate regions 212. In FIG. 5B, this can be seen upon the top of the fins 260. As can be seen in FIG. 5C and FIG. 5D, the dummy oxide layer is present on both the top and the sides of each semiconducting fin 260, as well as upon the STI layer 204.

The partially completed integrated circuit 200 on the wafer substrate 202 may be prepared by first etching the substrate to define the STI layer 204. Next, the fin stack 270 is formed by depositing the alternating layers of semiconducting nanosheets 272 and sacrificial layers 274 upon the substrate. A hard mask is applied and the fin stack is etched to obtain the semiconducting fin with fin portions in their desired location. An anisotropic etch of the sacrificial layers is performed, and inner dielectric spacers 218 are formed in these etched locations on the exposed exterior walls of the fin stack. The fin stack is then etched to create trenches in desired locations for the source/drain regions 210. Another anisotropic etch is performed on the newly exposed surfaces of the sacrificial layers within these trenches, and inner dielectric spacers 218 are again formed in the newly-etched locations. A dummy oxide layer 228 is then formed on exposed silicon surfaces. Epitaxial silicon is then deposited into the trenches to form the source/drain regions 210. A dummy gate material, such as polysilicon is then deposited over the substrate. Another photomask is applied and the dummy gate material is etched to create trenches over the source/drain regions and to form dummy gate regions 212. A low-k dielectric spacer 224 is then applied to the exposed vertical surfaces of the dummy gate regions. The ILD regions 220 are then formed over the source/drain regions. The CESL 226 is then applied over the three exposed sides of the ILD regions.

Referring now to optional step 104 of FIG. 1, which is not illustrated, the warpage of the substrate 202 is measured. Warpage can be measured using known metrology equipment and methods, such as 3-axis strain gauge measurement. The degree of warpage is usually measured in length (micrometers), where zero indicates no warpage (i.e. flat) and a higher value is undesirable. The warpage is generally measured as the difference from the center of the substrate, which is defined as zero. It is noted that the amount of acceptable warpage generally remains the same regardless of the die size (i.e. length and width). The measurements can be used to determine what kind of stress (compressive or tensile) should be applied to the substrate by the hard mask layer, and to determine the amount of stress to be applied.

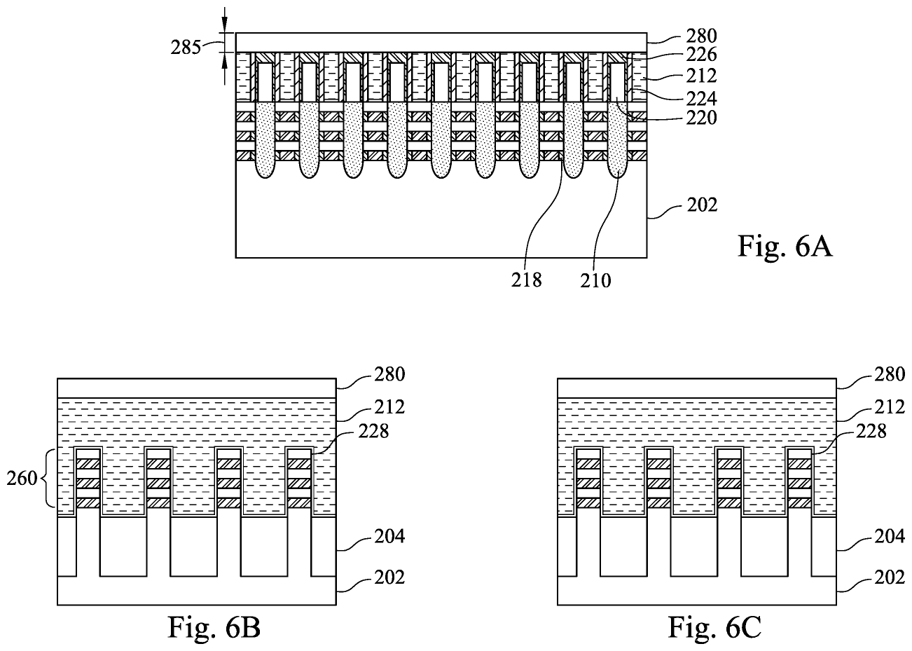

Referring now to step 105 of FIG. 4 as illustrated in FIGS. 6A-6C, a hard mask layer 280 having thickness 285 is applied upon the dummy gate regions 212 and the ILD regions 220. In some embodiments, the thickness 285 of the hard mask layer may be from about 600 angstroms up to about 900 nanometers. The hard mask layer is formed so as to apply the determined stress and the determined amount of stress.

The stress applied by the hard mask layer (i.e. compressive or tensile) can be changed by altering the growth conditions under which the hard mask layer is formed. For example, the stress can be changed based on the deposition temperature, the crystalline state, vacancies, grain boundaries, the lattice quality (i.e. amount of impurities), lattice mismatch, and the thickness of the layer. Generally, compressive stress will reduce the CD, and tensile stress will increase the CD.

In particular embodiments, the hard mask layer is formed from silicon nitride (SiₓN_{y}, 0<x, y≤1). The silicon nitride can be deposited using ALD (for high aspect ratio trench filling) or CVD. Common growth temperatures for silicon nitride range from 200° C. to 800° C. Silicon precursors for deposition may include silanes and halogenated silane. Examples may include but are not limited to tetraethyl orthosilicate (TEOS), trimethylsilane, tetramethylsilane, hexachlorodisilane (HCDS), iodosilane, and other chlorosilanes. Nitrogen precursors for deposition may include but are not limited to ammonia (NH₃), N₂, and N₂O. To facilitate dissociation of the precursors, a plasma source, such as ICP (Inductively Coupled Plasma) or CCP (Capacitively Coupled Plasma), may be used. To better control the dissociation rates of the precursor and the viscosity of the precursors flowing to the wafer substrate, other gases such as argon, hydrogen, or nitrogen may be included as well to facilitate dissocation or reduce the viscosity.

The stress of the hard mask layer, particularly when it is made of silicon nitride (SiN), can be tuned/controlled/changed through (1) changing the deposition or growth temperature to control the degree of thermal expansion of the resulting SiN layer; (2) using different precursors to change the crystalline qualities of the resulting layer; (3) changing how the precursors are dissociated to control the material that starts the growth of the SiN layer upon the substrate, to tune the quality of the interface between the substrate and SiN layer.

Generally, higher growth temperatures will lead to the formation of a layer with more tensile stress. For example, by raising the growth temperature into the range of 400° C. to 600° C., the stress of the SiN layer can increase 3.2 MPa/° C. for an SiN layer with a thickness of about 200 nm to about 300 nm.

An SiN layer can also be made to exert more tensile stress by reducing the amount of impurities in the SiN layer. This can be done, for example, by increasing the dissociation rates of the precursor by using plasma source or including gases such as argon or hydrogen.

In optional step 106 of FIG. 1, which is not illustrated, the warpage of the substrate 202 may be measured. This particular step may be useful in a continuous production process to measure the warpage after the SiN layer has been applied and provide feedback to the tool that performs the hard mask deposition step 105, so that the recipe for the hard mask layer deposited on a subsequent substrate can be better tuned to obtain the desired effect.

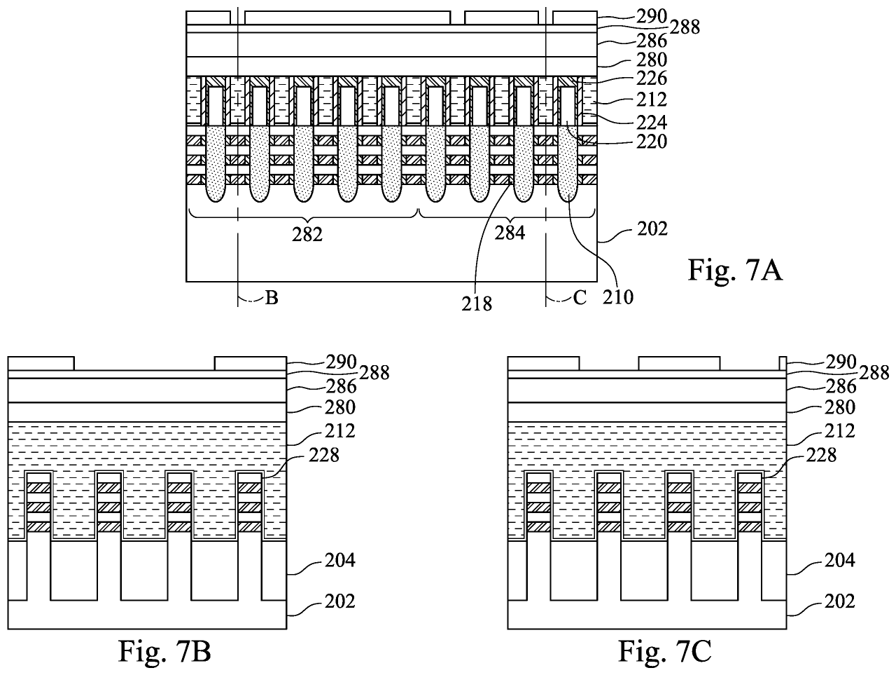

In optional step 108 of FIG. 4 as illustrated in FIGS. 7A-7C, a bottom layer 286 and/or a middle layer 288 can be applied over the hard mask layer 280. A spin-on-carbon (SoC) material is suitable for the bottom layer. A spin-on-glass material is commonly used for the middle layer. When used, the combination of the hard mask layer, the bottom layer, and the middle layer results in a tri-layer patterning etch system, which allows for better control of subsequent etching. Then, in step 110 of FIG. 1, a photoresist (PR) layer 290 is applied and patterned. In particular embodiments, extreme ultraviolet (EUV) light having a wavelength of about 13.5 nm is used for patterning, as this permits smaller feature sizes to be obtained. If the bottom layer and middle layer are not used, then the PR layer would be applied directly to the hard mask layer 280.

The resulting structure is illustrated in FIGS. 7A-7C. As illustrated in this example in FIG. 7A, the PR layer 290 is patterned to expose at least two dummy gate regions 212 that are widely spaced apart in a first region 282, i.e. along line Y1-Y1 of FIG. 5A (only one such dummy gate region is shown). The PR layer is also patterned to expose at least two dummy gate regions 212 that are closely spaced apart in a second region 284, i.e. along line Y2-Y2 of FIG. 5A.

As seen in FIG. 7B, along line Y1-Y1, the entire volume between the outer two semiconducting fins 260 will be exposed. As seen in FIG. 7C, along line Y2-Y2, a semiconducting fin remains covered by the hard mask layer between two exposed fins. As a result, the PR layer will define a set of isolated long trenches in the first region and a set of dense short trenches in the second region. These trenches will be defined over the long dummy gate regions of FIG. 5A.

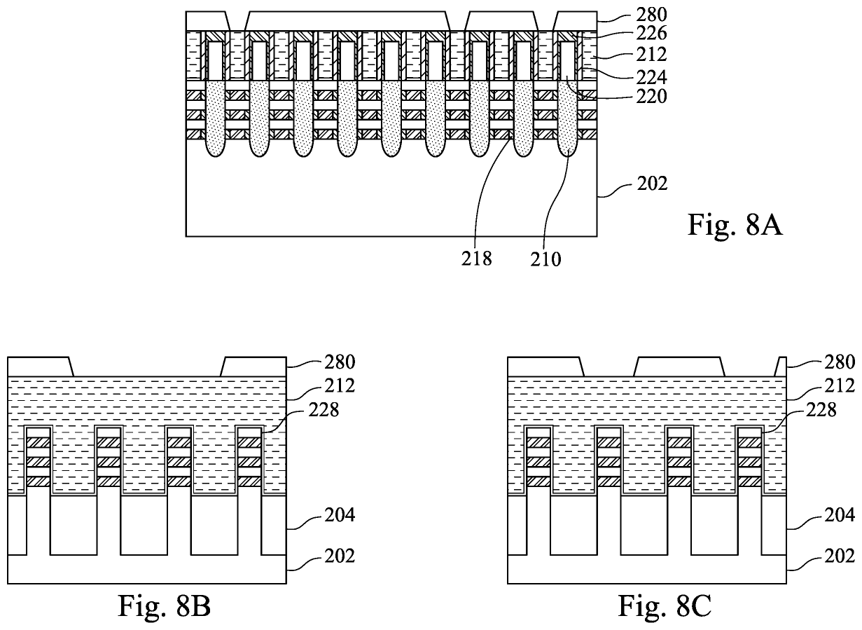

Next, in step 115 of FIG. 1, etching is performed to etch through the hard mask layer 280 and transfer the pattern to the hard mask layer. This may be referred to as Hard Mask Open (HMO). When present, the middle layer 288 and the bottom layer 286 are etched through first, using appropriate etchants. After removal of the bottom layer, the middle layer, and the PR layer, the resulting structure is seen in FIGS. 8A-8C. The hard mask layer is thus patterned to define a set of isolated long CPODE trenches in one region and a set of dense short CPODE trenches in another region.

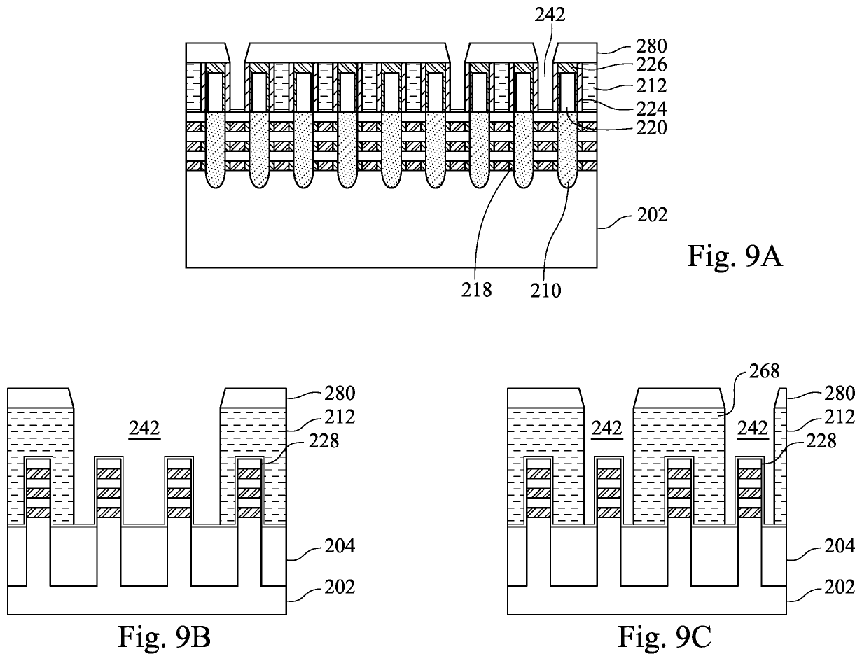

Then, in step 120 of FIG. 1, the exposed dummy gate regions are removed by etching. When the dummy gate region is formed from polysilicon, suitable etchants may include BCl₃, Cl₂, SiCl₄, HCl, O₂, HBr, SF₆, and/or NF₃, in appropriate combinations and ratios. The resulting structure is seen in FIGS. 9A-9C. As seen in FIG. 9B and FIG. 9C, the removal of each dummy gate region exposes three sides of the semiconducting fins 260 below that dummy gate region. The empty dummy gate region(s) may also be referred to herein an isolation volume 242. Referring back to FIG. 2A, it is noted that each isolation volume is bracketed by dummy gate material that acts as longitudinal sidewalls 241.

It is also noted that in the second region as seen in FIG. 9C, there is one non-exposed semiconducting fin located between two isolation volumes 242, and some of the dummy gate material (such as polysilicon) is not etched away, but instead remains. This material will act as a wall 268 and separate a long dummy gate region into a plurality of short isolation volumes 242. This will result in short trenches in the second region, as will be seen later. Referring back to FIG. 2A, the dielectric wall may be considered one of the longitudinal sidewalls 241 for each short trench.

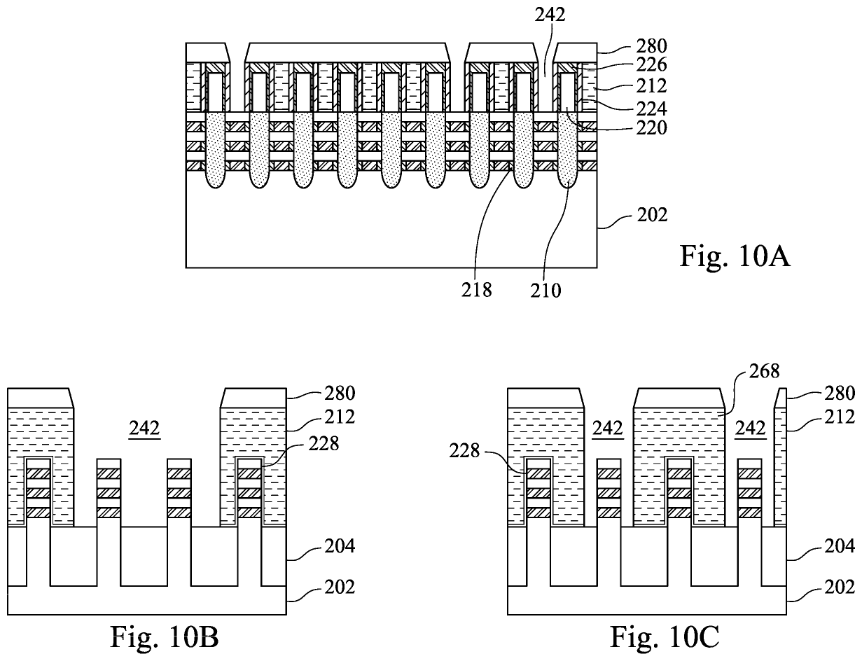

Next, in step 125 of FIG. 1, the exposed dummy oxide is removed from the semiconducting fins and the STI layer. FIGS. 10A-10C show the resulting structure. The two outer semiconducting fins are not affected as they are protected by the hard mask layer 280.

Then, in step 130 of FIG. 1, etching is performed to remove the exposed semiconducting fin portions and to form trenches 244 in the substrate. In particular embodiments, the etching is done through HBr/Cl₂ based plasma with O₂ or CO₂ addition in plasma tools. Pumping/Ar flush/SiO passivation (using SiCl₄/O₂ precursors) steps can also be included in the etching process.

Tools equipped with ICP, resonant antenna, or ECR coils enabling high density plasma generation may also be used for etching. Common pressure and temperature ranges for the process are about 0.1 m Torr to about 200 mTorr and about 10° C. to about 200° C., respectively. For ICP and resonant coil, the RF power generator may be operated to provide a source power to form plasma in the range of about 0 W to about 2500 W. For an ECR plasma generator, the source power usually ranges from about 200 W to about 1200 W. To facilitate directional etch by accelerating ions in the plasma, the RF bias power to the pedestal may be in a range of about 0 W to about 2000 W. Plasma pulsing techniques for source or bias power, usually with duty ratio between 5% to 95%, are also commonly used to reach a “sweet spot” that balances CD and depth.

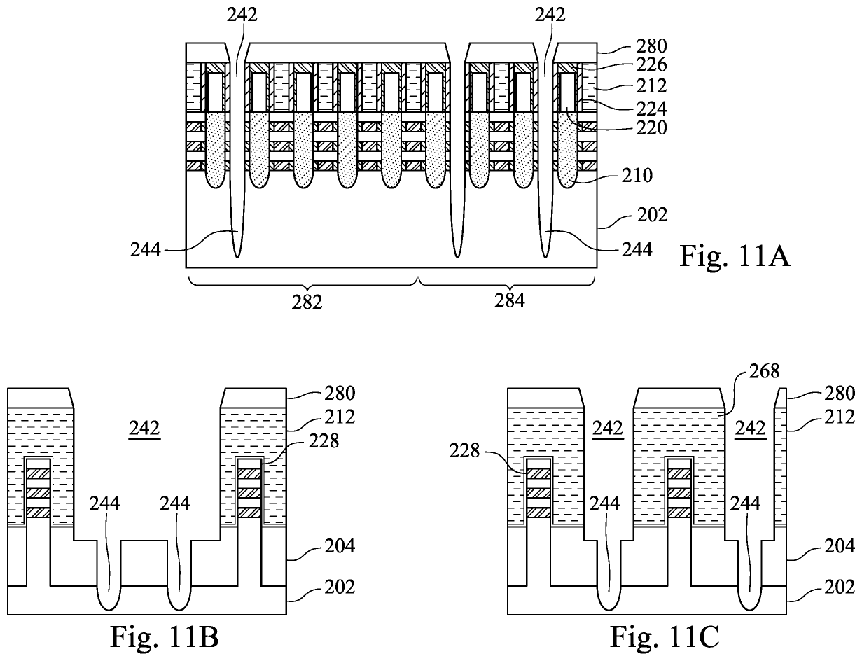

FIGS. 11A-11C show the resulting structure. As seen in FIG. 11A, there is one trench 244 illustrated on the left-hand side that is isolated in the first region 282, whereas on the right-hand side two trenches 244 are closely spaced apart, or dense, in the second region 284. The combination of an isolation volume 242 and a trench 244 may also be referred to as a CPODE trench.

Referring to FIG. 11A, it is noted that the etchant for the semiconducting nanosheet 272 and the sacrificial layer 274 does not etch the inner dielectric spacers 218. Thus, there is a protective layer between the trench and the source/drain regions 210 formed from epitaxial silicon (which can be etched by the same etchant for the semiconducting nanosheet). As better seen in FIG. 11B and FIG. 11C, a portion of the STI layer 204 may also be etched away along with the semiconducting fin portions. Put another way, the isolation volume 242 may extend into the STI layer.

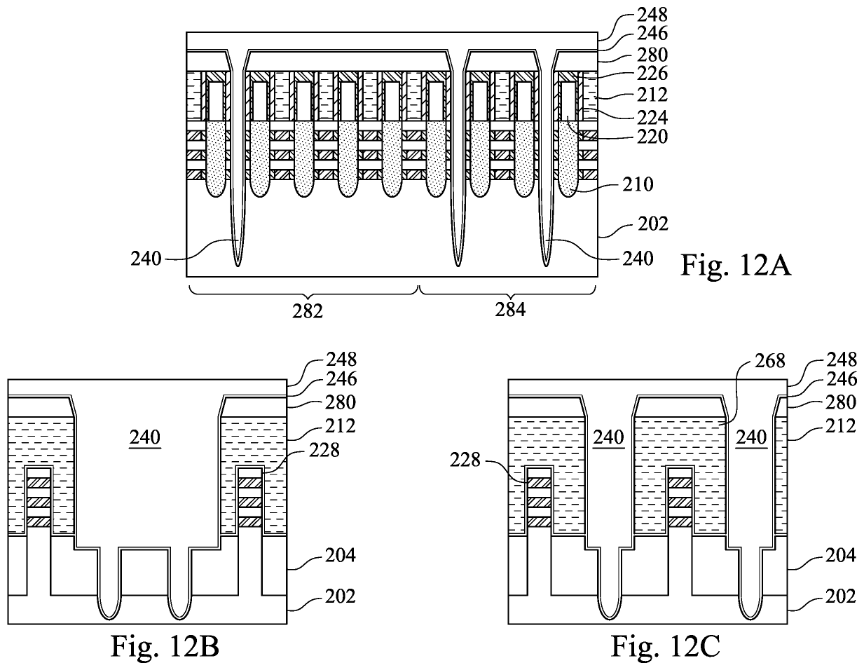

Then, in step 135 of FIG. 1, the CPODE trenches (isolation volume 242 and trench 244) are filled (or refilled) with at least one dielectric material to form CPODE structures 240 in the first region 282 and the second region 284. As illustrated in the structure of FIGS. 12A-12C, the walls of the trench and the isolation volume are lined with a first dielectric material 246. This may be done, for example, via ALD. In some particular embodiments, the first dielectric material is an oxide, such as a silicon oxide. The trench and the isolation volume are then filled with a second different dielectric material 248. This may be performed by deposition, as illustrated here. In some particular embodiments, the second dielectric material is a nitride, such as silicon nitride. Referring to FIG. 12A, the CPODE structure in the first region 282 is isolated, and the CPODE structures in the second region 284 are dense. Each CPODE structure also electrically isolates the source/drain regions on one side from those on the other side. As seen in FIG. 12C, the wall 268 may be considered as one of the longitudinal sidewalls of the dense short trenches. As a result, a set of isolated long dielectric structures and a set of dense short dielectric structures is formed.

In optional step 136 of FIG. 1, which is not illustrated, the warpage of the substrate 202 may be measured. Again, this particular step may be useful in a continuous production process to measure the warpage of the substrate and include the effect of the CPODE structure on the final warpage. This information can provide feedback to the tool that performs the hard mask deposition step 105, so that the recipe for the hard mask layer deposited on a subsequent substrate can be better tuned to obtain the desired effect.

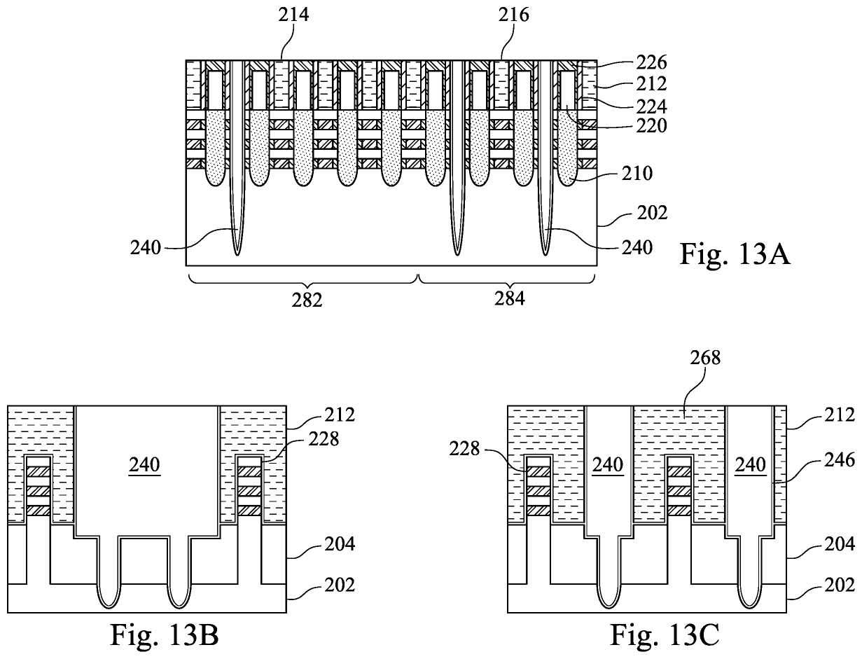

Continuing, then, in step 140 of FIG. 1, the substrate is planarized to remove the overfill dielectric materials and the hard mask layer 280. The resulting structure is illustrated in FIGS. 13A-13C. The remaining dummy gate regions 212 in the first region 282 and the second region 284 are now exposed. For example, a primary dummy gate 214 in the first region is exposed, as is a secondary dummy gate 216 in the second region.

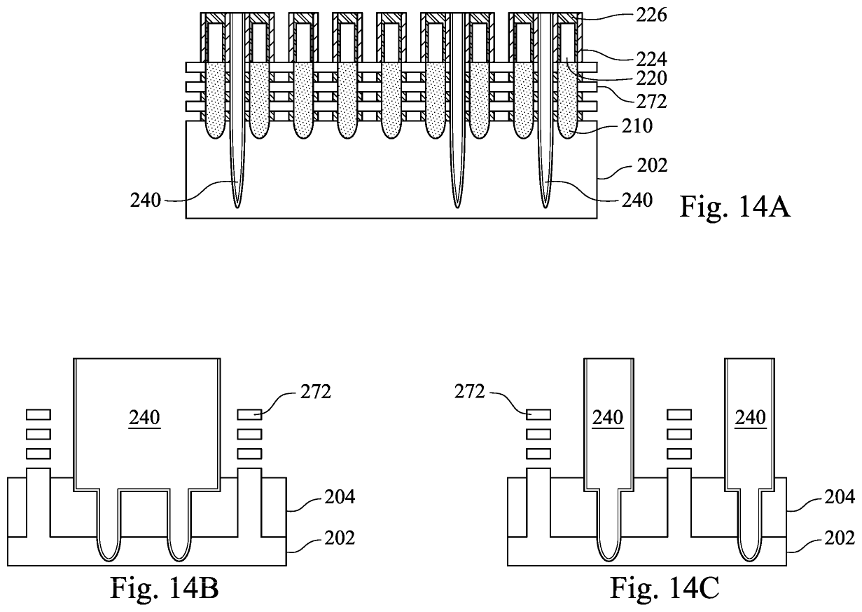

Next, in step 145 of FIG. 1, the dummy gate regions, such as the primary dummy gate 214 and the secondary dummy gate 216, are removed. Any remaining dummy oxide 228 (see FIG. 13B and FIG. 13C) is also removed. Then, in step 150, the sacrificial layers 274 in the semiconducting fins are removed. Both steps are typically performed by etching. It is noted that the sacrificial layers are removed after the CPODE structure is formed. The resulting structure is illustrated in FIGS. 14A-14C. These empty spaces after removing the dummy gate material may be referred to as gate volumes. Referring to FIG. 14B and FIG. 14C, the semiconducting nanosheets 272 are supported by the adjacent source/drain regions 210 (visible in FIG. 14A), and can also be referred to as semiconducting channels. Referring to FIG. 14C, the wall 268 has been removed and is no longer present.

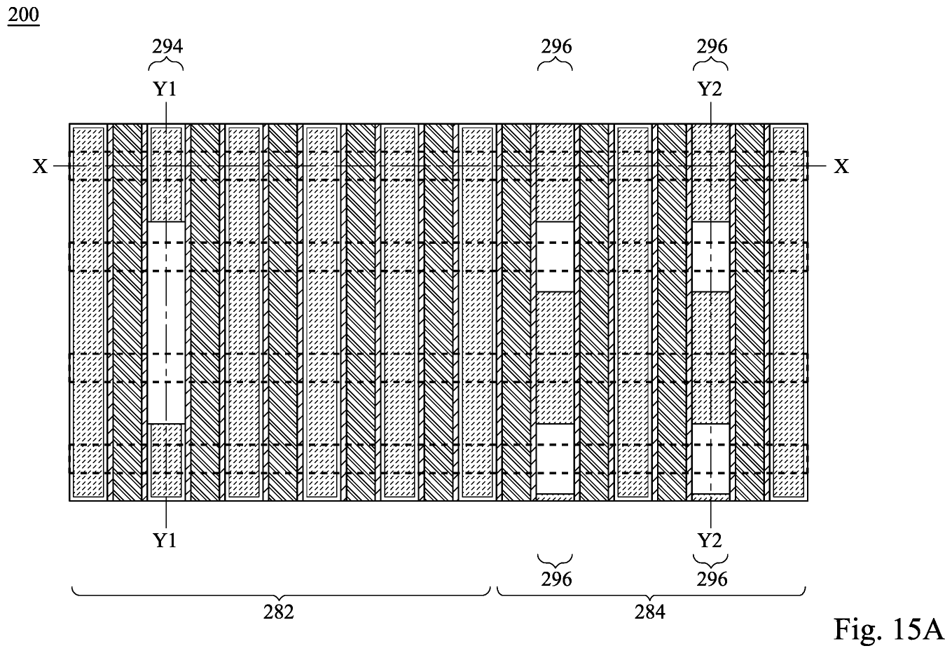

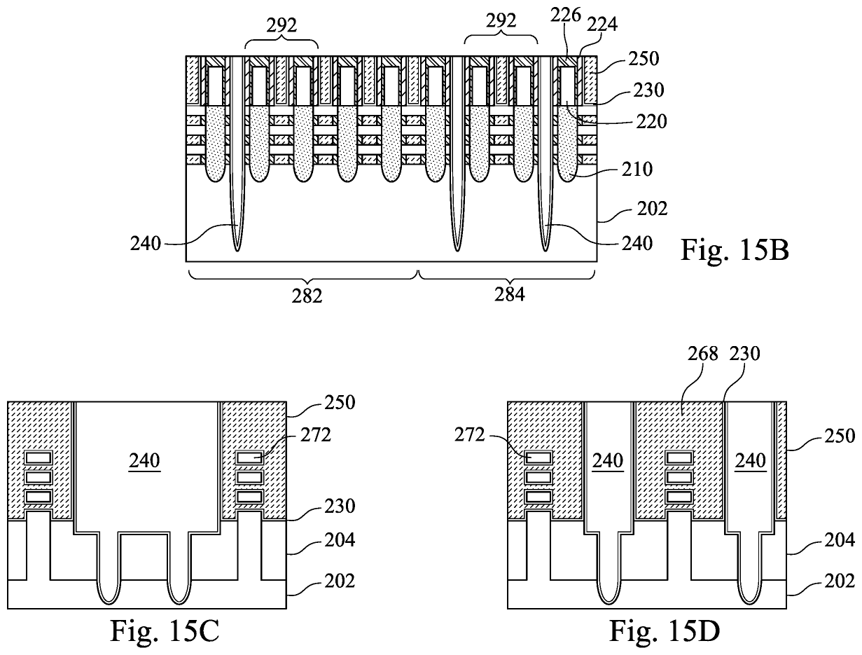

Next, in step 155 of FIG. 1 and as illustrated in FIGS. 15A-15D, a gate oxide layer 230 is applied to the semiconducting nanosheets/channels 272. This may be done, for example, using ALD. Then, in step 160, an electrically conductive gate material is applied to fill the gate volumes and form a gate electrode 250. Any suitable electrically conductive material may be used. In particular embodiments, a metal such as W, TiN, TiAl, Pt, Co, Rh, Pd, Ti, Ta, and the like is used. Thus, Gate-All-Around (GAA) transistors 292 are formed in both the first region 282 and the second region 284.

As seen in FIG. 15A, the first region 282 may be considered to include a set of isolated long dielectric structures (e.g. CPODE) 294. In the first region, only one isolated long dielectric structure is illustrated. The second region 284 may be considered to include a set of dense short dielectric structures 296. Four dense short dielectric structures are illustrated in a 2×2 array.

As illustrated in FIG. 15B, the first region 282 has five source/drain regions 210 and four gates 250, and thus may be considered to have four transistors. In contrast, the second region 284 has two source/drain regions 210 and one gate 250, and thus may be considered to have one transistor.

As previously mentioned, the depth loading is the difference between the etch depth of CPODE structures in a set of isolated long trenches/structures and the etch depth of CPODE structures in a set of dense short trenches/structures. To put it more shortly, the depth loading is ((isolated long trench depth) minus (dense short trench depth)). Thus, the depth loading may be positive or negative, and desirably is zero. Through the use of the methods of the present disclosure, in particular embodiments, the depth loading of the dielectric structures is within 60 nanometers of zero, i.e. ±60 nanometers. In some more specific embodiments, the depth loading of the dielectric structures is ±40 nanometers.

In addition, the average critical dimension of the set of isolated long dielectric structures may be 20 nanometers or less. Similarly, the average critical dimension of the set of dense short dielectric structures may be 20 nanometers or less. The average depth of the set of isolated long dielectric structures may be at least 180 nanometers. The average depth of the set of dense short dielectric structures also may be at least 180 nanometers.

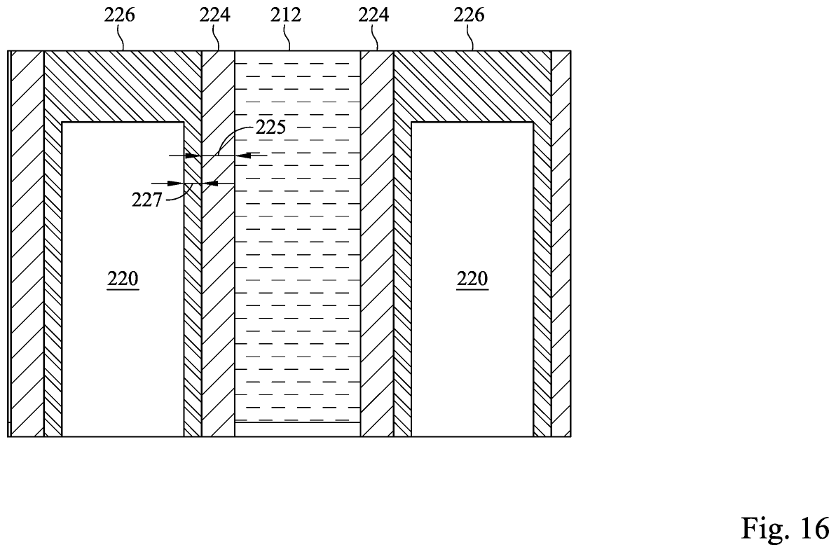

FIG. 16 is a magnified X-axis view showing a dummy gate region 212 flanked by two dielectric spacers 224 and two CESLs 226. Each dielectric spacer has a width 225. The side of each CESL (on the side of the ILD 220) has a width 227. In particular embodiments, the ratio of the dielectric spacer width 225 to the CESL width 227 may be about 8/3 or higher. In this regard, a higher ratio leads to lower parasitic capacitance.

As illustrated above, the sacrificial layers are removed and the gate electrode is formed after the CPODE structures are formed. This means the CPODE structures are formed during a front-end-of-line (FEOL) process, or in other words the CPODE structures are formed before the gate electrode material is applied to form a finished transistor. However, the methods of the present disclosure can also be practiced in a middle-end-of-line (MEOL) process after gate deposition and the transistors are formed.

Additional processing steps may be performed to obtain semiconductor devices containing the CPODE structures with reduced depth loading. The semiconductor devices might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

The methods of the present disclosure improve the depth loading of CPODE structures by reducing the depth gap between isolated dielectric structures and dense dielectric structures. This reduces leakage current, and permits consistent performance.

The present disclosure thus relates in various embodiments to methods for reducing a depth loading of dielectric structures on a substrate. A substrate is received that comprises a plurality of long dummy gate regions extending in a lateral direction. Each dummy gate region has a first dielectric spacer and a second dielectric spacer extending in the lateral direction and directly contacting opposite sides of the dummy gate region. A first continuous etch stop layer extends in the lateral direction and directly contacts the side of the first dielectric spacer opposite that of the dummy gate region. A second continuous etch stop layer extends in the lateral direction and directly contacts the side of the second dielectric spacer opposite that of the dummy gate region. A hard mask layer is formed over the substrate that exerts a compressive force. The hard mask layer is patterned to define a set of isolated long trenches and a set of dense short trenches over the plurality of long dummy gate regions. Etching is performed through the hard mask layer to form the set of isolated long trenches, with each long trench including longitudinal sidewalls of dummy gate material at opposite ends of the trench. Etching is also performed through the hard mask layer to form the set of dense short trenches. A plurality of short trenches is formed from a long dummy gate region, with each short trench including a longitudinal sidewall of dummy gate material and a dielectric wall separating adjacent short trenches. Each trench is then filled with at least one dielectric material to form a set of isolated long dielectric structures and a set of dense short dielectric structures on the substrate.

Also disclosed in various embodiments are other methods for reducing a depth loading of dielectric structures on a substrate. A substrate is received that comprises a plurality of long dummy gate regions extending in a lateral direction. Each dummy gate region has a first dielectric spacer and a second dielectric spacer extending in the lateral direction and directly contacting opposite sides of the dummy gate region. A first continuous etch stop layer extends in the lateral direction and directly contacts the side of the first dielectric spacer opposite that of the dummy gate region. A second continuous etch stop layer extends in the lateral direction and directly contacts the side of the second dielectric spacer opposite that of the dummy gate region. A hard mask layer is formed over the substrate that exerts a tensile force. The hard mask layer is patterned to define a set of isolated long trenches and a set of dense short trenches over the plurality of long dummy gate regions. Etching is performed through the hard mask layer to form the set of isolated long trenches, with each long trench including longitudinal sidewalls of dummy gate material at opposite ends of the trench. Etching is also performed through the hard mask layer to form the set of dense short trenches. A plurality of short trenches is formed from a long dummy gate region, with each short trench including a longitudinal sidewall of dummy gate material and a dielectric wall separating adjacent short trenches. Each trench is then filled with at least one dielectric material to form a set of isolated long dielectric structures and a set of dense short dielectric structures on the substrate.

Also disclosed in various embodiments are semiconductor devices that comprise a set of isolated long dielectric structures and a set of dense short dielectric structures on a substrate. Each dielectric structure comprises: a dielectric volume filled with at least one dielectric material; a first dielectric spacer and a second dielectric spacer directly contacting opposite lateral sides of the dielectric volume; a first continuous etch stop layer directly contacting a side of the first dielectric spacer opposite that of the given dielectric volume; a second continuous etch stop layer directly contacting a side of the second dielectric spacer opposite that of the given dielectric volume; and sidewalls of dummy gate material directly contacting opposite longitudinal sides of the dielectric volume. The depth loading of the semiconductor device is ±60 nanometers.

Still further disclosed in various embodiments are alternative methods for reducing a depth loading of dielectric structures on a substrate. A substrate is received that comprises a plurality of long dummy gate regions extending in a lateral direction. Each dummy gate region has a first dielectric spacer and a second dielectric spacer extending in the lateral direction and directly contacting opposite sides of the dummy gate region. A first continuous etch stop layer extends in the lateral direction and directly contacts the side of the first dielectric spacer opposite that of the dummy gate region. A second continuous etch stop layer extends in the lateral direction and directly contacts the side of the second dielectric spacer opposite that of the dummy gate region. A hard mask layer is formed over the substrate that exerts a tensile force. The hard mask layer is patterned to define a set of isolated long trenches and a set of dense long trenches over the plurality of long dummy gate regions. Etching is performed through the hard mask layer to form the set of long trenches, with each long trench including longitudinal sidewalls of dummy gate material at opposite ends of the trench. Each trench is then filled with at least one dielectric material to form a set of isolated long dielectric structures and a set of dense long dielectric structures on the substrate. The hard mask is removed, and remaining dummy gate regions are removed and filled with a gate material to form gate electrodes. A cut metal gate (CMG) structure is then formed that may extend through the dense long dielectric structures and convert them into dense short dielectric structures.

The methods, systems, and devices of the present disclosure are further illustrated in the following non-limiting working example, it being understood that the example is intended to be illustrative only and that the disclosure is not intended to be limited to the materials, conditions, process parameters and the like recited herein.

### EXAMPLES

### Example 1

Several wafers were prepared with CPODE structures that were made according to the methods of the present disclosure by applying a compressive stress through the hard mask layer. Isolated long trenches, isolated short trenches, dense long trenches, and dense short trenches were made. Long trenches had a length of 1000 nm, while short trenches had a length of nm. Isolated (ISO) trenches had a spacing of 10,000 nm, while dense trenches had a spacing of 100 nm.

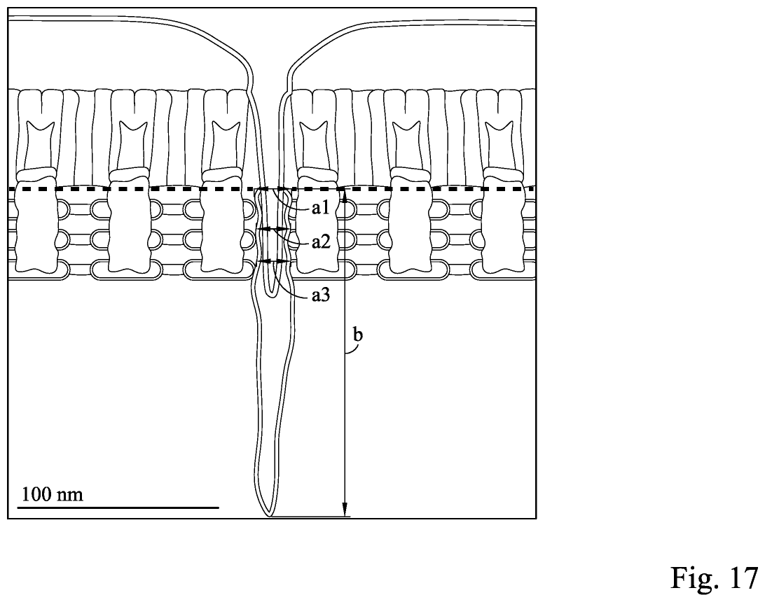

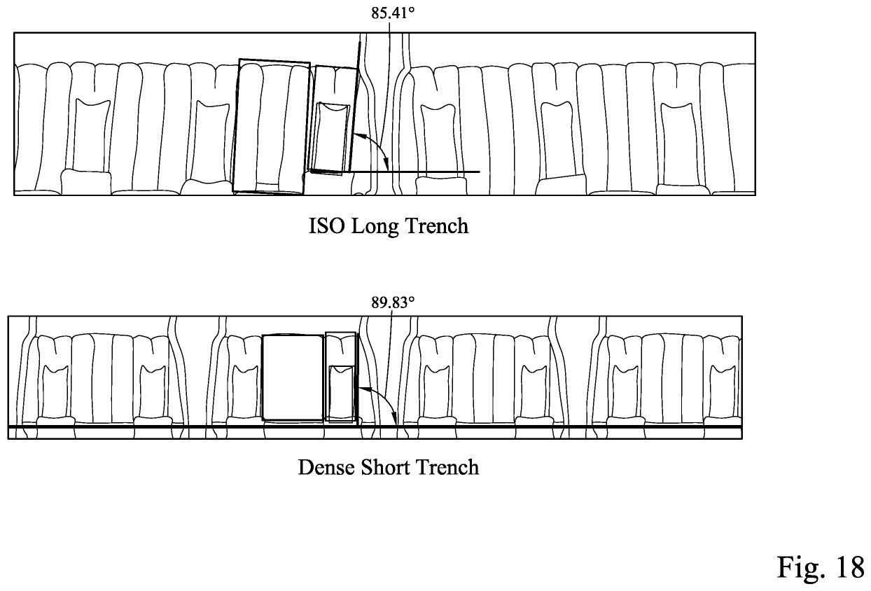

FIG. 17 is a line drawing of an isolated long trench. The semiconducting channels were formed from three nanosheets. The critical dimension (CD) of the CPODE structure at the level of the top nanosheet is indicated with the letter a1. The critical dimension of the CPODE structure at the level of the middle nanosheet is indicated with the letter a2. The critical dimension of the CPODE structure at the level of the bottom nanosheet is indicated with the letter a3. The depth of the CPODE structure is indicated with the letter b.

The CD of the CPODE (i.e. a1, a2, a3) should not be greater than 20 nm, or else damage might occur to the epitaxial silicon (i.e. source/drain) regions. The depth b of each CPODE structure should be a minimum of 180 nanometers (nm).

Measurements of the CPODE structures were made, and the results are presented in the following table:

TABLE B

| | | |
|---|---|---|
| Value | Item | Average (nm) |

ISO Long Pattern

| | | |
|---|---|---|
| a1 | Top Sheet CD | <20 |
| a2 | Middle Sheet CD | <20 |
| a3 | Bottom Sheet CD | <20 |
| b | Depth | 166 |

ISO Short Pattern

| | | |
|---|---|---|
| a1 | Top Sheet CD | <20 |
| a2 | Middle Sheet CD | 20 |
| a3 | Bottom Sheet CD | <20 |
| b | Depth | 210 |

Dense Long Pattern

| | | |
|---|---|---|
| a1 | Top Sheet CD | <20 |
| a2 | Middle Sheet CD | 22 |
| a3 | Bottom Sheet CD | 21 |
| b | Depth | 207 |

Dense Short Pattern

| | | |
|---|---|---|
| a1 | Top Sheet CD | <20 |
| a2 | Middle Sheet CD | <20 |
| a3 | Bottom Sheet CD | <20 |
| b | Depth | 200 |

The CD and depth requirements were met. The depth loading, calculated as the difference between the ISO Long pattern and the Dense Short pattern, was (166-200)=−34 nm.

### Example 2

Several wafers were prepared with CPODE structures that were made according to the methods of the present disclosure by applying a tensile stress through the hard mask layer. Isolated long trenches, isolated short trenches, dense long trenches, and dense short trenches were made with the same parameters as Example 1.

Measurements of the CPODE structures were made, and the results are presented in the following table:

TABLE C

| | | |
|---|---|---|
| Value | Item | Average (nm) |

ISO Long Pattern

| | | |
|---|---|---|
| a1 | Top Sheet CD | <20 |
| a2 | Middle Sheet CD | 21 |
| a3 | Bottom Sheet CD | <20 |
| b | Depth | 228 |

ISO Short Pattern

| | | |
|---|---|---|
| a1 | Top Sheet CD | <20 |
| a2 | Middle Sheet CD | <20 |
| a3 | Bottom Sheet CD | <20 |
| b | Depth | 204 |

Dense Long Pattern

| | | |
|---|---|---|
| a1 | Top Sheet CD | <20 |
| a2 | Middle Sheet CD | <20 |
| a3 | Bottom Sheet CD | <20 |
| b | Depth | 201 |

Dense Short Pattern

| | | |
|---|---|---|
| a1 | Top Sheet CD | <20 |
| a2 | Middle Sheet CD | <20 |
| a3 | Bottom Sheet CD | <20 |
| b | Depth | 206 |

The CD and depth requirements were met. The depth loading was (228-206)=+22 nm.

### Example 3

Several wafers were prepared with CPODE structures that were made according to the methods of the present disclosure by applying a tensile stress through the hard mask layer. Isolated long trenches and dense short trenches were made with the same parameters as Example 1. Whereas in Examples 1 and 2, the dielectric spacer was made using SiCON, in Example 3 the dielectric spacer was made using silicon oxide. Measurements of the CPODE structures were made, and the results are presented in the following table:

TABLE D

| | | |
|---|---|---|
| Value | Item | Average (nm) |

ISO Long Pattern

| | | |
|---|---|---|
| a1 | Top Sheet CD | <20 |
| a2 | Middle Sheet CD | <20 |
| a3 | Bottom Sheet CD | <20 |
| b | Depth | 153 |

Dense Short Pattern

| | | |
|---|---|---|
| a1 | Top Sheet CD | <20 |
| a2 | Middle Sheet CD | <20 |
| a3 | Bottom Sheet CD | <20 |
| b | Depth | 210 |

The CD and depth requirements were met. The depth loading was (153-210)=−57 nm.

### Example 4

Several wafers were prepared with CPODE structures that were made according to the methods of the present disclosure. FIG. 18 is a line drawing of isolated long trenches and dense short trenches. The bending of the CESL or ILD region next to the CPODE trench was measured, and the bending angle was the difference from vertical. As seen in FIG. 18, the bending angle of the CESL or ILD region in the ISO Long pattern was greater than 4°. The bending angle of the CESL or ILD region in the Dense Short pattern was less than 1°.

In well-controlled processes, the run-to-run CD variation may be in the range of +/−2 nm, and the depths of the trenches may be controlled within +/−5 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for reducing a depth loading of dielectric structures on a substrate, comprising:
receiving a substrate comprising a plurality of long dummy gate regions extending in a lateral direction, each dummy gate region having
a first dielectric spacer and a second dielectric spacer extending in the lateral direction and directly contacting opposite sides of the dummy gate region;
a first continuous etch stop layer extending in the lateral direction and directly contacting a side of the first dielectric spacer opposite that of the dummy gate region; and
a second continuous etch stop layer extending in the lateral direction and directly contacting a side of the second dielectric spacer opposite that of the dummy gate region;
forming a hard mask layer over the substrate that exerts a compressive force;
patterning the hard mask layer to define a set of isolated long trenches and a set of dense short trenches over the plurality of long dummy gate regions;
etching through the hard mask layer to form the set of isolated long trenches;
etching through the hard mask layer to form the set of dense short trenches, wherein a plurality of short trenches is formed from a long dummy gate region, with a wall of dummy gate material separating adjacent short trenches; and
filling each trench with at least one dielectric material to form a set of isolated long dielectric structures and a set of dense short dielectric structures on the substrate.

2. The method of claim 1, wherein an average critical dimension of the set of isolated long dielectric structures and an average critical dimension of the set of dense short dielectric structures is each 20 nanometers or less.

3. The method of claim 1, wherein an average depth of the set of isolated long dielectric structures and an average depth of the set of dense short dielectric structures is each at least 180 nanometers.

4. The method of claim 1, wherein the depth loading is ±60 nanometers.

5. The method of claim 1, wherein the first dielectric spacer and the second dielectric spacer have a Young's modulus of 75 GPa or less.

6. The method of claim 1, wherein the first dielectric spacer and the second dielectric spacer are made of silicon carboxynitride.

7. The method of claim 1, wherein a (carbon+nitrogen) content of the first dielectric spacer and the second dielectric spacer is each less than 5 mole %.

8. The method of claim 1, wherein the first continuous etch stop layer and the second continuous etch stop layer have a Young's modulus of about 250 GPa or higher.

9. The method of claim 1, wherein the first continuous etch stop layer and the second continuous etch stop layer are made of silicon nitride.

10. The method of claim 1, wherein a ratio of a thickness of the first dielectric spacer to a thickness of the first continuous etch stop layer is about 8/3 or higher.

11. The method of claim 1, wherein the dummy gate material has a Young's modulus of about 140 GPa to about 180 GPa.

12. The method of claim 1, wherein the dummy gate material is polysilicon.

13. A method for reducing a depth loading of dielectric structures on a substrate, comprising:
receiving a substrate comprising a plurality of long dummy gate regions extending in a lateral direction, each dummy gate region having
a first dielectric spacer and a second dielectric spacer extending in the lateral direction and directly contacting opposite sides of the dummy gate region;
a first continuous etch stop layer extending in the lateral direction and directly contacting a side of the first dielectric spacer opposite that of the dummy gate region; and
a second continuous etch stop layer extending in the lateral direction and directly contacting a side of the second dielectric spacer opposite that of the dummy gate region;
forming a hard mask layer over the substrate that exerts a tensile force;
patterning the hard mask layer to define a set of isolated long trenches and a set of dense short trenches over the plurality of long dummy gate regions;
etching through the hard mask layer to form the set of isolated long trenches;
etching through the hard mask layer to form the set of dense short trenches, wherein a plurality of short trenches is formed from a long dummy gate region, with a wall of dummy gate material separating adjacent short trenches; and
filling each trench with at least one dielectric material to form a set of isolated long dielectric structures and a set of dense short dielectric structures on the substrate.

14. The method of claim 13, wherein an average critical dimension of the set of isolated long dielectric structures and an average critical dimension of the set of dense short dielectric structures is each 20 nanometers or less.

15. The method of claim 13, wherein an average depth of the set of isolated long dielectric structures and an average depth of the set of dense short dielectric structures is each at least 180 nanometers.

16. The method of claim 13, wherein the depth loading is +60 nanometers.

17. The method of claim 13, wherein the first dielectric spacer and the second dielectric spacer have a Young's modulus of 75 GPa or less.

18. The method of claim 13, wherein the first continuous etch stop layer and the second continuous etch stop layer have a Young's modulus of about 250 GPa or higher.

19. A semiconductor device comprising a set of isolated long dielectric structures and a set of dense short dielectric structures thereon;
wherein each dielectric structure comprises:
a dielectric volume filled with at least one dielectric material;
a first dielectric spacer and a second dielectric spacer directly contacting opposite lateral sides of the dielectric volume;
a first continuous etch stop layer directly contacting a side of the first dielectric spacer opposite that of the given dielectric volume; and
a second continuous etch stop layer directly contacting a side of the second dielectric spacer opposite that of the given dielectric volume;
wherein the depth loading is ±60 nanometers.

20. The device of claim 19, wherein the depth loading is ±40 nanometers.
